(19) United States
(12) Patent Application Publication
(10) Pub. No.: US 2011/0233502 A1
(43) Pub. Date: Sep. 29, 2011

(54) NONVOLATILE MEMORY DEVICE

(75) Inventors: Takashi SHIGEOKA, Kanagawa (JP); Tetsuji Kunitake, Mie (JP); Hisashi Kato, Mie (JP); Kenji Aoyama, Kanagawa (JP); Kensuke Takahashi, Kanagawa (JP)

(73) Assignee: Kabushiki Kaisha Toshiba, Tokyo (JP)

(21) Appl. No.: 13/051,650

(22) Filed: Mar. 18, 2011

(30) Foreign Application Priority Data
Mar. 24, 2010 (JP) 2010-068547

(51) Int. Cl. H01L 45/00

(52) U.S. Cl. 257/2; 257/E45.003

(57) ABSTRACT

According to one embodiment, a nonvolatile memory device is provided, which includes a nonvolatile memory element in which an anode, a nonvolatile memory layer formed of a metal oxide film, and a cathode are stacked. The anode is formed of a metal nitride material and includes nitrogen more than a stoichiometric ratio of the metal nitride material. The cathode is formed of a metal material.

### CROSS-REFERENCE TO RELATED APPLICATIONS

This application is based upon and claims the benefit of priority from the prior Japanese Patent Application No. 2010-68547, filed on Mar. 24, 2010; the entire contents of which are incorporated herein by reference.

### FIELD

Embodiments described herein relate generally to a nonvolatile memory device.

### BACKGROUND

Recently, as a nonvolatile memory device, a ReRAM (Resistive Random Access Memory) attracts attention, which stores therein resistance value information on a variable resistive element that is electrically alterable, for example, a high resistance state and a low resistance state in a nonvolatile manner. Such a ReRAM is, for example, configured such that variable resistance memory cells in each of which a variable resistive element as a memory element and a rectifier element such as a diode are connected in series are arranged in an array at intersection portions of a plurality of bit lines that extend in parallel with a first direction and a plurality of word lines that extend in parallel with a second direction vertical to the first direction (for example, see Japanese Patent Application Laid-open No. 2009-99200). For example, the variable resistive element includes a variable resistive layer that is capable of changing a resistance value by voltage application and is formed of multiple oxide including transition elements, and an upper portion electrode layer and a lower portion electrode layer that are provided over and under the variable resistive layer and function as a barrier metal and an adhesion layer. As the upper portion electrode layer and the lower portion electrode layer, typically, material such as Pt, Au, Ag, TiAlN, TiN, TaN, and Rh/TaAlN is used.

The material of these upper portion electrode layer and lower portion electrode layer is selected depending on the material forming the variable resistive layer because switching between the high resistance state and the low resistance state is not performed properly depending on the combination with the variable resistive layer.

### BRIEF DESCRIPTION OF THE DRAWINGS

FIG. 1 is a diagram illustrating an example of a memory cell array configuration of a nonvolatile memory device according to embodiments;

FIG. 2 is a cross-sectional view schematically illustrating an example of a structure of a nonvolatile memory device according to a first embodiment;

FIG. 3A to FIG. 3C are diagrams schematically illustrating a model of a transition state between a high resistance state and a low resistance state in a variable resistive element;

FIG. 4A to FIG. 4H are cross-sectional views schematically illustrating an example of a procedure of a manufacturing method of the nonvolatile memory device in the first embodiment; and

FIG. 5 is a cross-sectional view schematically illustrating an example of a structure of a nonvolatile memory device according to a second embodiment.

### DETAILED DESCRIPTION

In general, according to one embodiment, a nonvolatile memory device is provided, which includes a nonvolatile memory element in which an anode, a nonvolatile memory layer formed of a metal oxide film, and a cathode are stacked. The anode is formed of a metal nitride material and includes nitrogen more than a stoichiometric ratio of the metal nitride material. The cathode is formed of a metal material.

A nonvolatile memory device according to the embodiments will be explained below in detail with reference to the accompanying drawings. The present invention is not limited to these embodiments. Moreover, cross-sectional views of the nonvolatile memory device used in the following embodiments are schematic ones and a relation between the thickness and the width of a layer, the ratio of the thicknesses of the respective layers, and the like may be different from realistic ones. Furthermore, the film thickness illustrated below is an example and is not limited to this.

### First Embodiment

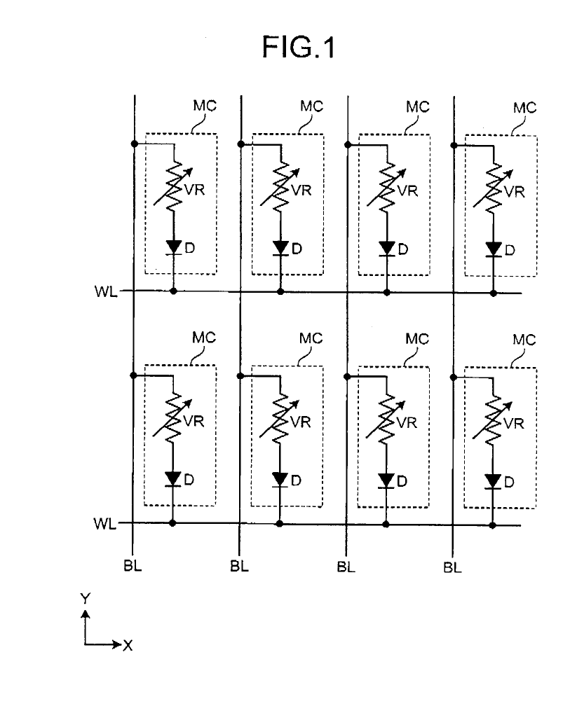

FIG. 1 is a diagram illustrating an example of a memory cell array configuration of a nonvolatile memory device according to embodiments. In FIG. 1, a right and left direction in the drawing is an X direction and a direction vertical to the X direction in the drawing is a Y direction. A plurality of word lines WL that extend in the X direction (row direction) and a plurality of bit lines EL that extend in the Y direction (column direction) at a height different from the word lines WL are arranged to intersect with each other and a resistance change memory cell (hereinafter, also called simply, a memory cell) MC in which a variable resistive element VR and a rectifier element D are connected in series is arranged at each intersection portion. In this example, the variable resistive element VR is connected to the bit line BL at one end and is connected to the word line WL at the other end via the rectifier element D.

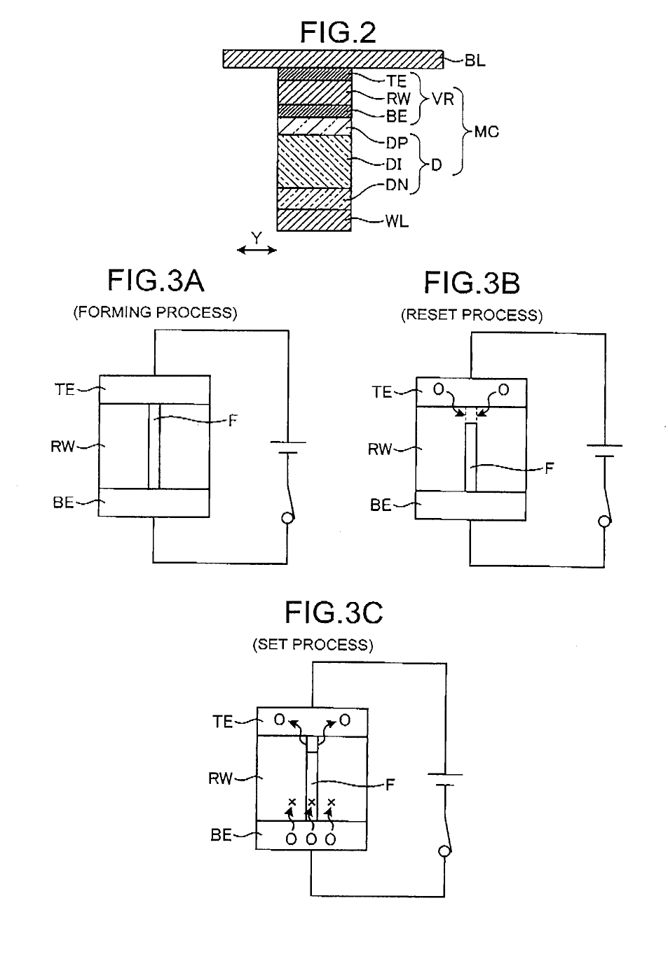

FIG. 2 is a cross-sectional view schematically illustrating an example of a structure of a nonvolatile memory device according to the first embodiment. FIG. 2, for example, illustrates a state of a portion of a cross section on the bit line BL along the Y direction in FIG. 1. On the word line WL that extends in the X direction, the rectifier element D and the variable resistive element VR forming the memory cell MC are stacked and the bit line BL that extends in the Y direction is formed on the variable resistive element VR.

The rectifier element D is formed of a material having a rectification such as a Schottky diode, a PN junction diode, and a PIN diode and is formed on the word line WL. In the present embodiment, the case is illustrated as an example in which the rectifier element D is formed of a polysilicon layer having a PIN structure foamed by stacking an N-type polysilicon film DN with the thickness of about 20 nm, an I-type polysilicon film DI with the thickness of about 110 nm, and a P-type polysilicon film DP with the thickness of about 20 nm in order from the side of the word line WL. Moreover, in this example, the rectifier element D is arranged so that current flows from the bit line BL to the word line WL.

The variable resistive element VR includes a lower portion electrode layer BE, a variable resistive layer RW as a nonvolatile memory layer, and an upper portion electrode layer TE. The variable resistive layer RW is formed of a metal oxide film capable of switching between a high resistance state and a low resistance state by controlling a voltage value and an application time. As the metal oxide film, for example, a metal oxide film including at least one element of Hf, Zr, Ni, Co, Al, Mn, Ti, Ta, W, and the like can be exemplified. When being used as the nonvolatile memory device, in the variable resistive layer RW, oxygen deficiency is introduced and a filament that is an electrical conduction path is locally formed.

In the variable resistive element VR, an electrode on the upstream side is an anode and an electrode on the downstream side is a cathode with reference to a direction in which current flows. Therefore, in the example in FIG. 2, the lower portion electrode layer BE functions as a cathode and the upper portion electrode layer TE functions as an anode.

The cathode, i.e., the lower portion electrode layer BE in the example in FIG. 2 is formed of a metal material or a metal nitride material that does not impair the variable resistivity of the variable resistive layer RW by reacting with the variable resistive layer RW. As such a lower portion electrode layer BE, for example, it is possible to use at least one metal material selected from Pt, Au, Ag, Ru, Ir, Co, Al, Ti, W, Mo, Ta, and the like or nitride of at least one metal material selected from Ti, W, Mo, Ta, and the like. In the case of forming the lower portion electrode layer BE with metal nitride, the ratio of a metal element is large compared with the stoichiometric ratio of metal nitride. When the composition formula of metal nitride represented by the stoichiometric ratio is MₐN_{y}, (M represents a metal element and, a and b represent positive integers) and the composition formula of metal nitride used in the lower portion electrode layer BE is MₓN_{y}, x is selected to satisfy the following expression (1). Moreover, in the following, metal nitride having the composition formula MₓN_{y} that satisfies expression (1) is called metal-rich metal nitride.

x>ay/b (1)

The anode, i.e., the upper portion electrode layer TE in the example in FIG. 2 is formed of a metal nitride material that does not impair the variable resistivity of the variable resistive layer RW by reacting with the variable resistive layer RW. As such an upper portion electrode layer TE, for example, it is possible to use nitride of at least one metal material selected from Ti, W, Mo, Ta, and the like. The upper portion electrode layer TE is formed such that the ratio of a nitrogen element is large compared with the stoichiometric ratio of metal nitride. When the composition formula of metal nitride represented by the stoichiometric ratio is MₐN_{b} and the composition formula of metal nitride used in the upper portion electrode layer TE is MₓN_{y}, y is selected to satisfy the following expression (2). Moreover, in the following, metal nitride having the composition formula MₓN_{y} that satisfies expression (2) is called nitrogen-rich metal nitride.

y>bx/a (2)

Transition between the high resistance state and the low resistance state in the resistance change memory is explained. FIG. 3A to FIG. 3C are diagrams schematically illustrating a model of a transition state between the high resistance state and the low resistance state in the variable resistive element. Typically, immediately after forming the resistance change memory, the variable resistive layer RW is in an insulating state, so that a forming process of applying a high voltage to the memory cell MC (between the upper portion electrode layer TE and the lower portion electrode layer BE) to lower the resistance is performed. As shown in FIG. 3A, a current path called a filament F is generated in the memory cell MC by the forming process. This filament F is considered to be formed by continuous oxygen deficient regions in the variable resistive layer RW. Therefore, the variable resistive layer RW becomes a low resistance state. The forming process enables the memory cell MC to function as a nonvolatile memory element.

Because the variable resistive layer RW is in the low resistance state after the forming process, a reset process of making the variable resistive layer RW in the high resistance state is performed. In the reset process, when voltage is applied to the memory cell MC and current reaches a predetermined current amount, the variable resistive layer RW becomes the high resistance state by Joule heat. This is considered to be because oxygen is supplied from the anode, i.e., the upper portion electrode layer TE to the filament F as shown in FIG. 3B. When a metal material or a metal-rich metal nitride material is used for the lower portion electrode layer BE and a nitrogen-rich metal nitride material is used for the upper portion electrode layer TE as in the present embodiment again, the filament F is oxidized by oxygen supplied from the upper portion electrode layer TE (anode) in the similar manner and the variable resistive layer RW becomes the high resistance state.

On the other hand, a set process of making the variable resistive layer RW in the low resistance state is performed on the memory cell MC that becomes the high resistance state by the reset process. In the set process, when voltage is applied to the memory cell MC, the variable resistive layer RW becomes the low resistance state. This is considered to be because the oxygen deficiency occurs in the filament F near the anode, i.e., the upper portion electrode layer TE as shown in FIG. 3C. When a metal material or a metal-rich metal nitride material is used for the lower portion electrode layer BE and a nitrogen-rich metal nitride material is used for the upper portion electrode layer TE as in the present embodiment, while the upper portion electrode layer TE (anode) that excessively includes nitrogen easily releases oxygen, the lower portion electrode layer BE (cathode) that excessively includes metal captures oxygen from the lower portion electrode layer BE side and oxygen becomes difficult to diffuse to the upper portion electrode layer TE side in the variable resistive layer RW, so that the filament F is prevented from being oxidized.

In this manner, the lower portion electrode layer BE is formed of a metal material or a metal-element-rich metal nitride material and the upper portion electrode layer TE is formed of a nitrogen-rich metal nitride material, so that it becomes possible to cause oxidation and reduction of the filament F in the variable resistive layer RW in the reset process and the set process.

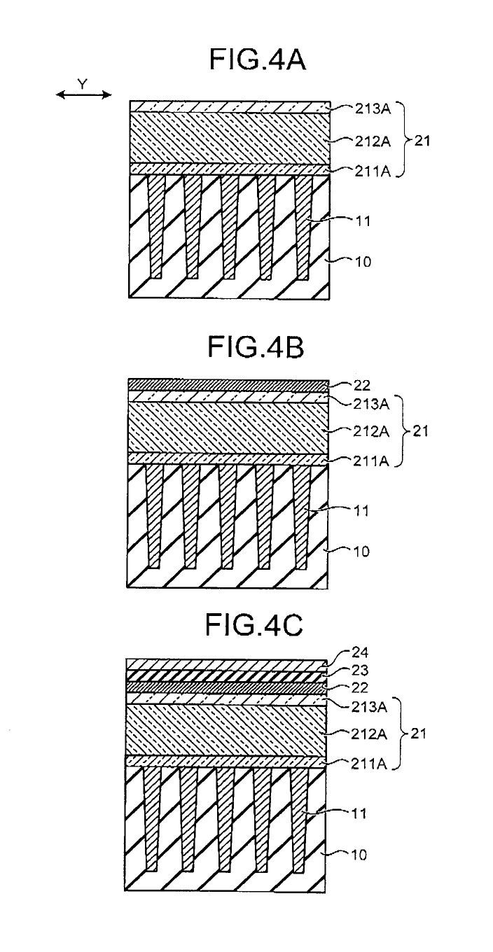

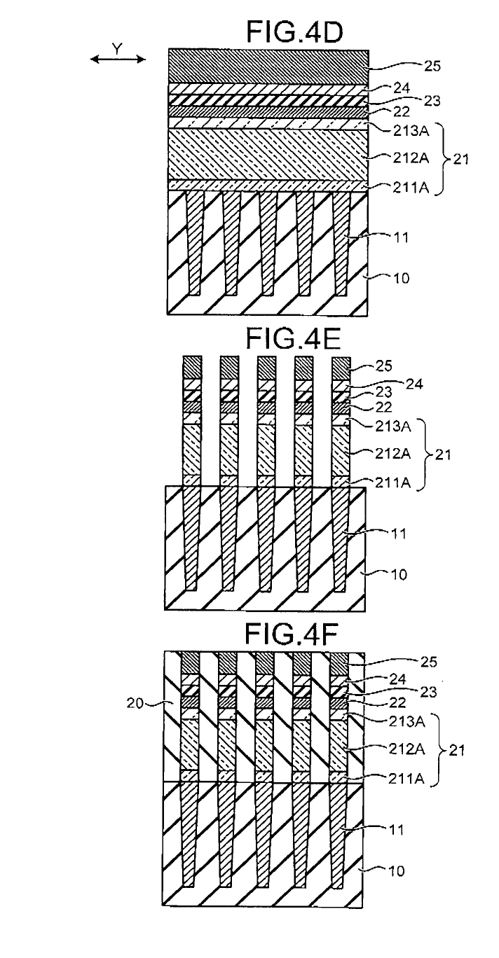

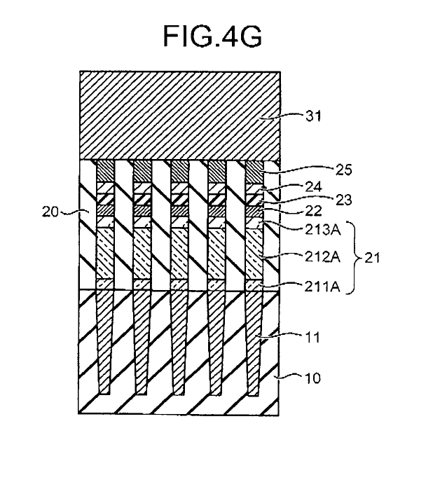

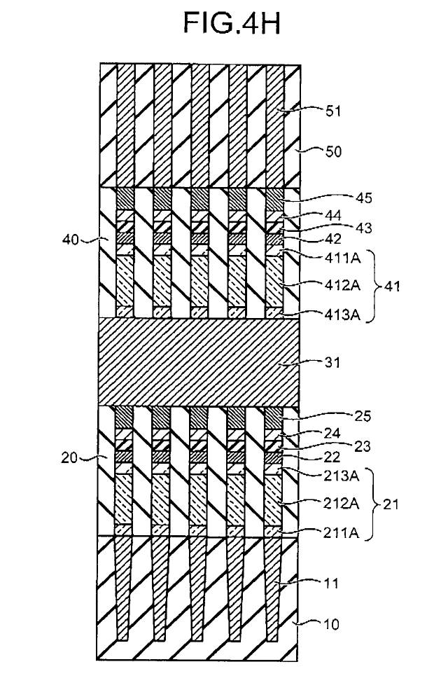

Next, the manufacturing method of the nonvolatile memory device illustrated in FIG. 2 is explained. FIG. 4A to FIG. 4H are cross-sectional views schematically illustrating an example of a procedure of the manufacturing method of the nonvolatile memory device in the first embodiment. In this example, explanation is given for the case of forming a plurality of the memory cells MC with reference to the cross section along the bit line BL in FIG. 1 as an example.

First, as shown in FIG. 4A, a first inter-layer dielectric film 10 is formed above a substrate such as a not-shown Si substrate, and first wires 11 (the word lines WL) that extend in the X direction are formed in this first inter-layer dielectric film 10 by a method such as a damascene method. An element such as a CMOS (Complementary Metal-Oxide Semiconductor) transistor is formed on the substrate of the lower layer of the first inter-layer dielectric film 10. Next, on the first inter-layer dielectric film 10 in which the first wires 11 are formed, an N-type amorphous silicon film 211A with the thickness of about 20 nm, an I-type amorphous silicon film 212A with the thickness of about 110 nm, and a P-type amorphous silicon film 213A with the thickness of about 20 nm are deposited in order by a film forming method such as the CVD (Chemical Vapor Deposition) method to form a rectifier layer 21. The N-type amorphous silicon film 211A is obtained by depositing a silicon film while introducing N-type impurities such as P (phosphorus), the I-type amorphous silicon film 212A is obtained by depositing a silicon film in an environment of avoiding introduction of impurities, and the P-type amorphous silicon film 213A is obtained by depositing a silicon film while introducing P-type impurities such as B (boron).

Thereafter, as shown in FIG. 4B, a lower portion electrode layer 22 with the thickness of about 5 nm is formed on the rectifier layer 21 by a method such as the sputtering method or the CVD method. Because the rectifier layer 21 has a structure in which the N-type amorphous silicon film 211A is formed on the side of the first wires 11, the lower portion electrode layer 22 is formed on the P-type amorphous silicon film 213A. In other words, the lower portion electrode layer 22 becomes a cathode. Therefore, as the lower portion electrode layer 22, a metal film or a metal-rich metal nitride film can be used. When forming the metal-rich metal nitride film, the film formation is performed under the condition that metal included in the lower portion electrode layer 22 becomes larger than the stoichiometric ratio.

Next, as shown in FIG. 4C, a variable resistive layer 23 with the thickness of about 10 nm formed of, for example a HfO film and an upper portion electrode layer 24 with the thickness of about 5 nm are stacked to be formed on the lower portion electrode layer 22 by a method such as the sputtering method or the CVD method. Because the upper portion electrode layer 24 becomes an anode, a nitrogen-rich metal nitride film is formed as the upper portion electrode layer 24. At this time, the film formation is performed under the condition that nitrogen included in the upper portion electrode layer 24 becomes larger than the stoichiometric ratio.

Moreover, as shown in FIG. 4D, a cap film 25 is formed on the upper portion electrode layer 24 by a film forming method such as the sputtering method. As this cap film 25, for example, a W film can be used. The cap film 25 is a film introduced in view of the process for connecting the upper portion electrode layer 24 with a second wire 31 of the upper layer.

Next, as shown in FIG. 4E, not-show resist is applied to the cap film 25, which is patterned to be a desired pattern by a lithography technique to form a mask. Then, the cap film 25, the upper portion electrode layer 24, the variable resistive layer 23, the lower portion electrode layer 22, and the rectifier layer 21 are processed by the anisotropic etching such as the RIE (Reactive Ion Etching) method to form a memory cell array pattern in which columnar memory cell patterns are two-dimensionally arranged. Pt this time, each columnar memory cell pattern has a structure in which the rectifier layer 21, the lower portion electrode layer 22, the variable resistive layer 23, the upper portion electrode layer 24, and the cap film 25 are stacked in order on the first wire 11.

Thereafter, as shown in FIG. 4F, a gap between the memory cell patterns processed into a columnar shape is filled by depositing a second inter-layer dielectric film 20 to be higher than the upper surface of the cap film 25. In this example, an HDP-USG (High density Plasma-Undoped Silicate Glasses) film formed by, for example, the plasma CVD method is deposited as the second inter-layer dielectric film 20. Then, the upper surface of the second inter-layer dielectric film 20 is flattened by a method such as the CMP (Chemical Mechanical Polishing) method until the upper surface of the cap film 25 is exposed. If the flattening is performed without forming the cap film 25, the upper portion electrode layer 24 and the variable resistive layer 23 may be subjected to the CMP process along with retraction of the upper surface of the second inter-layer dielectric film 20. If the upper portion electrode layer 24 and the variable resistive layer 23 are subjected to the CMP process, the characteristics may change, which is not preferable. Thus, the cap film 25 is formed on the upper portion electrode layer 24 to prevent the upper portion electrode layer 24 from being subjected to the CMP process, thereby preventing degradation of the characteristics.

Next, as shown in FIG. 4G, a not-shown third inter-layer dielectric film is formed on the cap film 25 and the second inter-layer dielectric film 20, and the upper surface thereof is flattened. Thereafter, a resist material is applied to the third inter-layer dielectric film and a mask is formed to have an opening shape corresponding to the second wires 31 (the bit lines BL) on the formation position of the memory cell patterns by the lithography technique. Thereafter, the third inter-layer dielectric film is etched by the RIE method or the like by using this mask until the cap film 25 is exposed to form trenches for the second wire formation, and a metal material such as W is embedded in the trenches to form the second wires 31 (the bit lines BL) that extend in the Y direction. Consequently, a first memory layer is formed.

Thereafter, as shown in FIG. 4H, it is applicable to stack a plurality of structures in each of which memory cells are sandwiched between upper and lower wires that are orthogonal to each other by repeating the above process the required number of times. FIG. 4H illustrates the case of forming two layers. In the second memory layer, a rectifier layer 41, a lower portion electrode layer 42, a variable resistive layer 43, an upper portion electrode layer 44, and a cap film 45 are processed into columnar memory cell patterns on the second wire 31 (the bit line BL) and a fourth inter-layer dielectric film 40 is embedded between the memory cell patterns. Moreover, a fifth inter-layer dielectric film 50 is formed on the fourth inter-layer dielectric film 40 and third wires 51 (the word lines WL) are formed by being embedded in the fifth inter-layer dielectric film 50 to extend in the X direction by the damascene method.

In the case of the second memory layer, the upper layer is the third wires 51 (the word lines WL), so that the rectifier layer 41 is formed to cause current to flow from the bit line BL to the direction of the word line WL. In other words, the rectifier layer 41 has a structure in which a P-type amorphous silicon film 413A, an I-type amorphous silicon film 412A, and an N-type amorphous silicon film 411A are stacked in order on the second wire 31. Moreover, because the direction in which current flows in the rectifier layer 41 is different from the first memory layer, the lower portion electrode layer 42 in the second layer becomes an anode and is formed of a nitrogen-rich metal nitride film and the upper portion electrode layer 44 becomes a cathode and is formed of a metal film or a metal-rich metal nitride film. Consequently, the second memory layer is formed. Moreover, in the case of forming a multilayered structure, it is only necessary to form such that an odd memory layer has a structure similar to the above first memory layer and an even memory layer has a structure similar to the above second memory layer by a procedure similar to the above procedure. In this manner, the structure is obtained in which the bit lines or the word lines are shared between adjacent upper and lower memory layers.

Then, the heat treatment is performed to crystallize and activate the rectifier layers 21 and 41 formed of the amorphous silicon films 211A to 213A and 411A to 413A. Consequently, the nonvolatile memory device is obtained.

In the above explanation, the case is illustrated in which the rectifier layer 21 and the variable resistive layer 23 are stacked in this order on the first wire 11, however, the variable resistive layer 23 and the rectifier layer 21 can be stacked in this order on the first wire 11. Moreover, the case is illustrated in which a semiconductor layer having a PIN junction structure is used as the rectifier layer, however, a diode having a PN junction structure, a Schottky junction structure, or the like can be used, or an MIM (Metal-Insulator-Metal) structure, an SIS (Silicon-Insulator-Silicon) structure, or the like can be used.

Moreover, the manufacturing method of the nonvolatile memory device is not limited to the above. For example, after forming the first wire layer, the first rectifier layer, the first lower portion electrode layer, the first variable resistive layer, the first upper portion electrode layer, and the first cap film, the portion from the first cap film to the first wire layer is processed into line and space patterns that extend in the first direction. Next, the inter-layer dielectric film is embedded between the processed structures, the second wire layer, the second rectifier layer, the second lower portion electrode layer, the second variable resistive layer, the second upper portion electrode layer, and the second cap film are formed on the inter-layer dielectric film in the state where the first cap film is exposed, the portion from the second cap film to the first rectifier layer is processed into line and space patterns that extend in the second direction orthogonal to the first direction, and the inter-layer dielectric film is embedded between the processed structures. Such process is performed a plurality of times, and finally, the wire layer is formed on the inter-layer dielectric film from which the cap film of the lower layer is exposed, the portion up to the rectifier layer formed on the wire layer immediately thereunder is processed into the line and space shape in the direction different from the line and space patterns formed in the lower layer, and the inter-layer dielectric film is embedded between the processed structures. Consequently, it is possible to obtain the nonvolatile memory device having a structure in which the variable resistance memory cells in each of which the rectifier layer, the lower portion electrode layer, the variable resistive layer, the upper portion electrode layer, and the cap film are processed into a columnar shape are sandwiched at the intersection positions of the upper and lower wire layers that are orthogonal to each other.

In the first embodiment, a metal film or a metal-rich metal nitride film is used for an electrode (cathode) on the downstream side of current flow in the variable resistive element VR and a nitrogen-rich metal nitride film is used for an electrode (anode) on the upstream side. Consequently, in the set process of making the variable resistive layer RW in the low resistance state, oxygen is easily released near the anode and oxygen supplied from the cathode side is captured by a metal element forming the cathode in the cathode, so that it is possible to eliminate concerns that the variable resistive layer RW becomes the high resistance state by oxygen supplied from the cathode after the set process. In other words, it is possible to prevent that a switching operation fails in each memory cell MC. As a result, effects are obtained in that a switching probability that is the ratio of the memory cell MC that does not perform switching with respect to the number of all the memory cells MC in the memory cell array can be lowered and tolerance of the variable resistive element VR can be improved.

### Second Embodiment

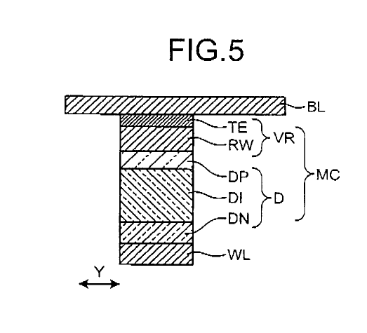

FIG. 5 is a cross-sectional view schematically illustrating an example of a structure of a nonvolatile memory device according to the second embodiment. In the second embodiment, the structure is such that the lower portion electrode layer BE as a cathode of the variable resistive element VR is omitted compared with FIG. 2 in the first embodiment. In this example, the rectifier element D is formed of polysilicon and the variable resistive layer RW is formed of an oxide film including at least one metal element selected from the group of Hf, Zr, Ni, Co, Al, Mn, Ti, Ta, and W. Components that are the same as those in the first embodiment are given the same reference numerals and explanation thereof is omitted.

Si forming the rectifier element D has a high electronegativity compared with a metal element forming the variable resistive layer RW, so that oxygen supplied from the rectifier element D side in the set process is bound to Si forming the rectifier element D. In other words, because the rectifier element D functions in the similar manner to a metal film or a metal-rich metal nitride film forming a cathode (the lower portion electrode layer BE) in the first embodiment, the cathode (the lower portion electrode layer BE) can be omitted in such structure.

Such a nonvolatile memory device can be manufactured by a method similar to the manufacturing method explained in the first embodiment.

According to the second embodiment, the rectifier element D is formed of Si that is an element whose electronegativity is higher than a metal element forming the variable resistive layer RW, so that oxygen supplied from the rectifier element D side to the variable resistive layer RW in the set process is captured in the rectifier element D, whereby it is possible to prevent that oxygen is supplied to the variable resistive layer RW and a filament that becomes the low resistance state becomes the high resistance state again. Moreover, because the rectifier element D functions equivalent to the cathode of the variable resistive element VR, the cathode can be omitted, thus enabling to obtain an effect that the structure of the nonvolatile memory device is simplified.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A nonvolatile memory device comprising a nonvolatile memory element in which an anode, a nonvolatile memory layer formed of a metal oxide film, and a cathode are stacked, wherein
the anode is formed of a metal nitride material and includes nitrogen more than a stoichiometric ratio of the metal nitride material, and
the cathode is formed of a metal material.

2. The nonvolatile memory device according to claim 1, wherein the cathode is at least one metal material selected from the group consisting of Pt, Au, Ag, Ru, Ir, Co, Al, Ti, W, Mo, and Ta.

3. The nonvolatile memory device according to claim 1, further comprising a rectifier element that is connected to the nonvolatile memory element in series.

4. The nonvolatile memory device according to claim 3, wherein the rectifier element is any of a Schottky diode, a PN junction diode, a PIN diode, a Metal-Insulator-Metal structure, and a Silicon-Insulator-Silicon structure.

5. The nonvolatile memory device according to claim 1, wherein the nonvolatile memory element is a variable resistive element.

6. The nonvolatile memory device according to claim 5, wherein the variable resistive element is a metal oxide film including at least one element selected from the group consisting of Hf, Zr, Ni, Co, Al, Mn, Ti, Ta, and W.

7. The nonvolatile memory device according to claim 1, wherein the anode is nitride of at least one metal selected from the group consisting of Ti, Ta, and W.

8. The nonvolatile memory device according to claim 1, wherein the nonvolatile memory element is arranged to be sandwiched between a plurality of first wires that extend in a first direction and a plurality of second wires that extend in a second direction at a height different from the first wires at each intersectional position of the first wires and the second wires.

9. A nonvolatile memory device comprising a nonvolatile memory element in which an anode, a nonvolatile memory layer formed of a metal oxide film, and a cathode are stacked, wherein
the anode is formed of a metal nitride material and includes nitrogen more than a stoichiometric ratio of the metal nitride material, and
the cathode is formed of a metal nitride material and includes a metal element more than a stoichiometric ratio of the metal nitride material.

10. The nonvolatile memory device according to claim 9, wherein the cathode is nitride of at least one metal selected from the group consisting of Ti, Ta, and W.

11. The nonvolatile memory device according to claim 9, further comprising a rectifier element that is connected to the nonvolatile memory element in series.

12. The nonvolatile memory device according to claim 11, wherein the rectifier element is any of a Schottky diode, a PN junction diode, a PIN diode, a Metal-Insulator-Metal structure, and a Silicon-Insulator-Silicon structure.

13. The nonvolatile memory device according to claim 8, wherein the nonvolatile memory element is a variable resistive element.

14. The nonvolatile memory device according to claim 13, wherein the variable resistive element is a metal oxide film including at least one element selected from the group consisting of Hf, Zr, Ni, Co, Al, Mn, Ti, Ta, and w.

15. The nonvolatile memory device according to claim 9, wherein the anode is nitride of at least one metal selected from the group consisting of Ti, Ta, and W.

16. The nonvolatile memory device according to claim 9, wherein the nonvolatile memory element is arranged to be sandwiched between a plurality of first wires that extend in a first direction and a plurality of second wires that extend in a second direction at a height different from the first wires at each intersection position of the first wires and the second wires.

17. A nonvolatile memory device comprising:
a rectifier element; and
a nonvolatile memory element that includes a nonvolatile memory layer that is provided on an upstream side with respect to a direction in which current flows in the rectifier element to be in contact with the rectifier element and is formed of a metal oxide film and an electrode layer that is provided on a side opposite to the rectifier element with respect to the nonvolatile memory layer, wherein
the electrode layer is formed of a metal nitride material and includes nitrogen more than a stoichiometric ratio of the metal nitride material, and
the rectifier element is formed of a semiconductor material formed of an element whose electronegativity is higher than that of a metal element in the metal oxide film.

18. The nonvolatile memory device according to claim 17, wherein
the nonvolatile memory element is a variable resistive element formed of a metal oxide film that includes at least one element selected from the group consisting of Hf, Zr, Ni, Co, Al, Mn, Ti, Ta, and W, and
the rectifier element is formed of Si.

19. The nonvolatile memory device according to claim 17, wherein the electrode layer is nitride of at least one metal selected from the group consisting of Ti, Ta, and W.

20. The nonvolatile memory device according to claim 17, wherein the nonvolatile memory element is arranged to be sandwiched between a plurality of first wires that extend in a first direction and a plurality of second wires that extend in a second direction at a height different from the first wires at each intersection position of the first wires and the second wires.
